(19) United States
(12) Patent Application Publication
(10) Pub. No.: US 2023/0088848 A1
(43) Pub. Date: Mar. 23, 2023

(54) YTTRIUM ALUMINUM COATING FOR PLASMA PROCESSING CHAMBER COMPONENTS

(71) Applicant: Lam Research Corporation, Fremont, CA (US)

(72) Inventors: Lin XU, Fremont, CA (US); David Joseph WETZEL, Santa Clara, CA (US); Satish SRINIVASAN, Newark, CA (US); Robin KOSHY, Fremont, CA (US); John Michael KERNS, Livermore, CA (US); John DAUGHERTY, Fremont, CA (US)

(21) Appl. No.: 17/792,109

(22) PCT Filed: Jan. 21, 2021
(86) PCT No.: PCT/US2021/014419

§ 371 Date: Jul. 11, 2022

Related U.S. Application Data
(60) Provisional application No. 62/965,008, filed on Jan. 23, 2020.
(60) Provisional application No. 63/039,820, filed on Jun. 16, 2020.

(51) Int. Cl. C23C 24/08; C23C 4/11; C23C 4/08; C04B 41/50

(52) U.S. Cl. CPC C23C 24/085; C23C 4/11; C23C 4/08; C04B 41/5035; C04B 41/5031

(57) ABSTRACT

A component of a plasma processing chamber having a coating on at least one surface that comprises yttrium aluminum. The coating is an aerosol deposited coating from a powder mixture of an yttrium oxide powder and an aluminum-containing powder and having an yttrium to aluminum ratio of 4:1 to 1:4 by molar number. The coating can be annealed to form a porous ternary oxide.

### CROSS-REFERENCE TO RELATED APPLICATIONS

This application claims the benefit of U.S. Provisional Patent Application No. 62/965,008, filed on Jan. 23, 2020, and U.S. Provisional Patent Application No. 63/039,820, filed on Jun. 16, 2020. The foregoing applications are hereby incorporated by reference herein for all purposes.

### BACKGROUND

The present disclosure generally relates to the manufacturing of semiconductor devices. More specifically, the disclosure relates to plasma chamber components used in manufacturing semiconductor devices.

During semiconductor wafer processing, plasma processing chambers are used to process semiconductor devices. Plasma processing chambers are subjected to plasmas, which may degrade components in the plasma processing chambers. Components of the plasma processing chamber that are degraded by plasma is a source of contaminants. Ceramic alumina (aluminum oxide (Al₂O₃)) is a common material used for components in plasma processing chambers, as alumina is somewhat plasma etch-resistant. However, it would be desirable to provide such components with even more plasma etch-resistant coatings.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

According to an embodiment, a method is provided for coating a component of a plasma processing chamber. The component body is provided. A coating of a powder mixture of an yttrium oxide powder and an aluminum-containing powder is aerosol deposited onto at least one surface of the component body. The coating has an yttrium to aluminum ratio of 4:1 to 1:4 by molar number.

According to another embodiment, a component of a plasma processing chamber is provided. The component body has a coating on a surface of the component body and the coating comprises a porous ternary oxide.

According to yet another embodiment, coating on a surface of the component body of a plasma processing chamber is provided. The coating is a deposited coating formed from a powder mixture of an yttrium oxide powder and an aluminum-containing powder.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIGS. 2A-E are schematic views of a component processed according to an embodiment.

FIG. 3 is a schematic view of a plasma processing chamber that may be used in an embodiment.

### DETAILED DESCRIPTION

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

Ceramic alumina (aluminum oxide (Al₂O₃)) is a common component material for plasma processing chamber components. Ceramic alumina may be used for items such as dielectric inductive power windows or gas injectors. Alumina has some plasma etch resistance. More etch-resistant coatings would provide additional protection to such plasma chamber components.

According to embodiments described herein, a component of a plasma processing chamber is provided with a coating that is more etch-resistant. The coating is deposited using a powder mixture of an yttrium oxide (Y₂O₃) powder and an aluminum-containing powder. The resulting coating that is deposited on the compomonent is a yttium aluminum coating that provides additional protection to the component.

According to some embodiments, the resulting coating on the component is a porous ternary oxide coating that is made porous by annealing the coating after deposition, as described in more detail below. Porous coatings can be desirable for plasma chamber components because the porosity of the material helps improve adhesion of the chamber by-products to the chamber component in that the by-products are adhered on the rougher, porous surface. Also, as noted above, the ceramic nature of the material provides plasma etch resistance.

A common method for manufacturing porous ceramics is to impregnate a polymer foam structure with ceramic slurry. The impregnated foam structure is then fired at a high temperature to remove the polymer matrix. Such a method is a cost effective way of making bulk porous ceramics, but cannot be used in the case of ceramic coating because the coating is so thin and the high temperatures required for firing would likely cause damage to the bonding of the ceramic to the substrate. Moreover, the manufacture of porous structures of ternary oxide materials requires raw powder of those materials, which are more difficult and more expensive to procure.

In some embodiments described herein, the porous coating of a plasma chamber component is a porous ternary oxide coating comprising yttrium aluminum garnet (Y₃Al₁₅O₁₂ (YAG)), yttrium aluminum monoclinic (Y₄Al₁₂O₉ (YAM)), or yttrium aluminum perovskite (YAlO₃ (YAP)). According to these embodiments, a mixture of yttrium oxide (Y₂O₃) and alumina powder is deposited on a ceramic substrate/component. It will be noted that yttrium oxide is also known as yttria. The ceramic component with the deposited mixture of yttria and alumina powder is then annealed at a temperature greater than about 900° C. to create a porous coating of ternary phase YAG, YAM, or YAP. The annealing generates a great deal of porosity, resulting in a ternary oxide coating that is extremely porous. As mentioned above, the porosity helps adhesion of chamber by-products. According to some embodiments, the component having the deposited powder mixture of yttria and alumina powder is annealed at a temperature in a range of about 900° C.-1300° C. for a period of at least about one hour and up to about 24 hours.

The methods described herein provide economical and convenient methods of forming the porous ternary oxide coatings. As mentioned above, a powder mixture of yttria and alumina powder are used to form the coatings. YAG, YAM, or YAP powder can also be used to form porous YAG, YAM, or YAP coatings, respectively. However, YAG, YAM, and YAP powders are extremely expensive. Forming YAG, YAM, or YAP coatings using yttria and alumina powders is therefore a more cost effective method of forming porous YAG, YAM, or YAP coatings.

The deposition of the powder mixture of yttria and alumina can be performed using aerosol deposition at room temperature to a thickness in a range of about 1-20 microns (μm). After annealing, the thickness of the coating may increase by up to about 10%. Thus, in some embodiments, the thickness of the coating after annealing can be in a range of about 1.05-21 μm. In other embodiments, the thickness of the coating after annealing can be in a range of about 1.1-22 μm. Other methods of deposition for forming a YAG or YAM coating include plasma spray of the YAG or YAM powders. However, plasma spray does not provide a coating structure that is as dense as powder that is deposited using aerosol deposition, and plasma spray is performed at very high temperatures (e.g., about 2000° C.).

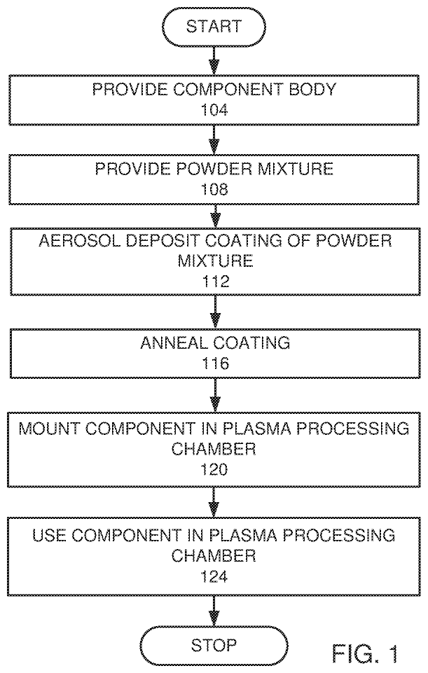

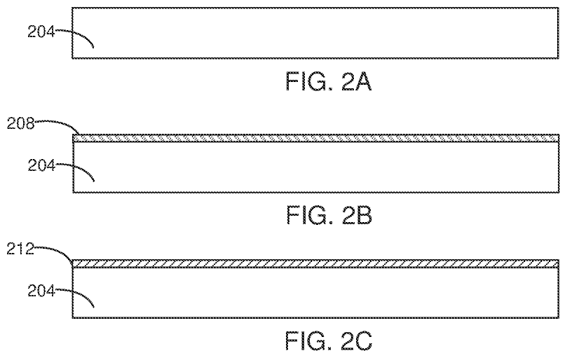

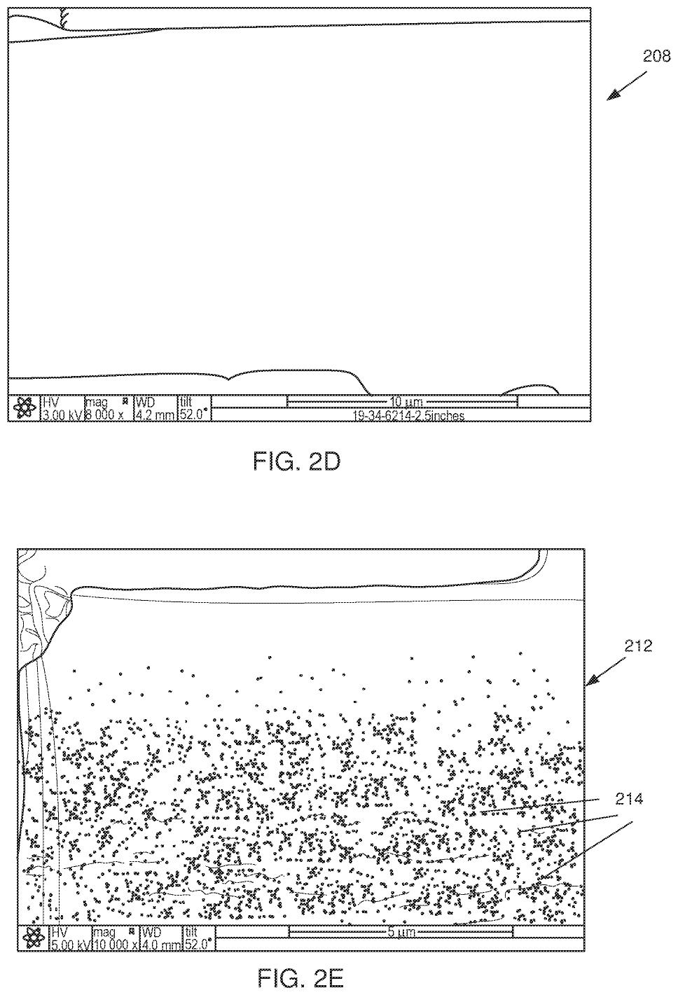

To facilitate understanding, FIG. 1 is a high level flow chart of a process used in an embodiment. A component body is provided (step 104). FIG. 2A is a schematic cross-sectional view of a component body 204 that is used in an embodiment. In the illustrated embodiment, the component body 204 is a ceramic alumina dielectric inductive power window.

A powder mixture of yttrium oxide powder and an aluminum-containing powder is provided (step 108). In this example, an yttrium oxide powder is mixed with an aluminum oxide powder. In other embodiments, an yttrium oxide powder is mixed with an aluminum powder.

An aerosol deposition coating of the powder mixture is then deposited on the surface of the component body 204 (step 112). Aerosol deposition is achieved by passing a carrier gas through a fluidized bed of solid powder mixture. Driven by a pressure difference, the powder mixture particles are accelerated through a nozzle, forming an aerosol jet at its outlet. The aerosol is then directed at the surface of the component body 204, where the aerosol jet impacts the surface with high velocity. The powder mixture particles break up into solid nanosized fragments, forming a coating. Optimization of carrier gas species, gas consumption, standoff distance, and scan speed provides high-quality coatings. The powder mixture and aerosol deposition are tuned so that the aerosol deposition coating has an yttrium to aluminum ratio of 4:1 to 1:4 by molar number. As noted above, aerosol deposition can take place at room temperature. FIG. 2B is a schematic cross-sectional view of the component body 204 after the aerosol deposition coating 208 of the powder mixture has been deposited. According to an embodiment, the component body 204 with the aerosol deposition coating 208 of the powder mixture is mounted in a plasma processing chamber (step 120).

To form a porous ternary oxide coating 212, the coating 208 can be annealed (step 116). In this embodiment, the coating is heated to a temperature greater than 900° C. The annealing causes the yttrium oxide powder to combine with the aluminum-containing powder to form one or more of YAG, YAM, and YAP. In an embodiment, the anneal is performed at a temperature between 900° C. to 1000° C. to form YAP. In another embodiment, the anneal is performed at a temperature between 1000° C. and 1100° C. to form YAM. In another embodiment, the anneal is performed at a temperature between 1100° C. to 1300° C. to form YAG. FIG. 2C is a schematic cross-sectional view of the component body 204 after the aerosol deposition coating of the powder mixture has been annealed to form an annealed coating 212 of one or more of YAG, YAM, or YAP. In this illustrated embodiment, this annealed coating 212 is a porous ternary oxide coating.

FIG. 2D is a cross-section image of the coating 208 after aerosol deposition of the powder mixture of yttria and alumina powder. FIG. 2E a cross-section image of the porous coating 212 after annealing of the aerosol deposited coating 208 of yttria and alumina powder mixture. As shown in FIG. 2E, the coating 212 has numerous pores 214. Thus, the coating 212 has additional porosity after annealing as compared to the coating 208 before annealing. The pores 214 represent the porosity of the coating 212.

The porosity of the coating 212 is the voids to bulk ratio of the coating 212. In the embodiments described herein , the porosity of the coating 212 is about 1-20%, where porosity is the volume of voids/total volume×100%. In some embodiments, the porosity of the coating 212 is about 5-20%. In other embodiments, the porosity of the coating 212 is about 1-10%. In still other embodiments, the porosity of the coating 212 is about 5-10%. Porosity can be measured by water intrusion methods, such as the Archimedes method. Other methods of measuring porosity, such as measuring the pressure increase of a volume of an enclosure in which the porous material is placed when the volume of the enclosure is reduced.

The component body 204 is mounted in a plasma processing chamber (step 120). In the illustrated example, the component body 204 is mounted in the plasma processing chamber as a dielectric inductive power window. The plasma processing chamber is used to process a substrate (step 124), where a plasma is created within the chamber to process a substrate, such as etching the substrate, and the coating 208, 212 is exposed to the plasma. The coating 208, 212 provides increased etch resistance to protect the component body 204. According to embodiments in which the coating 212 is annealed, the porosity of the annealed coating 212 provides improved adhesion of chamber by-products.

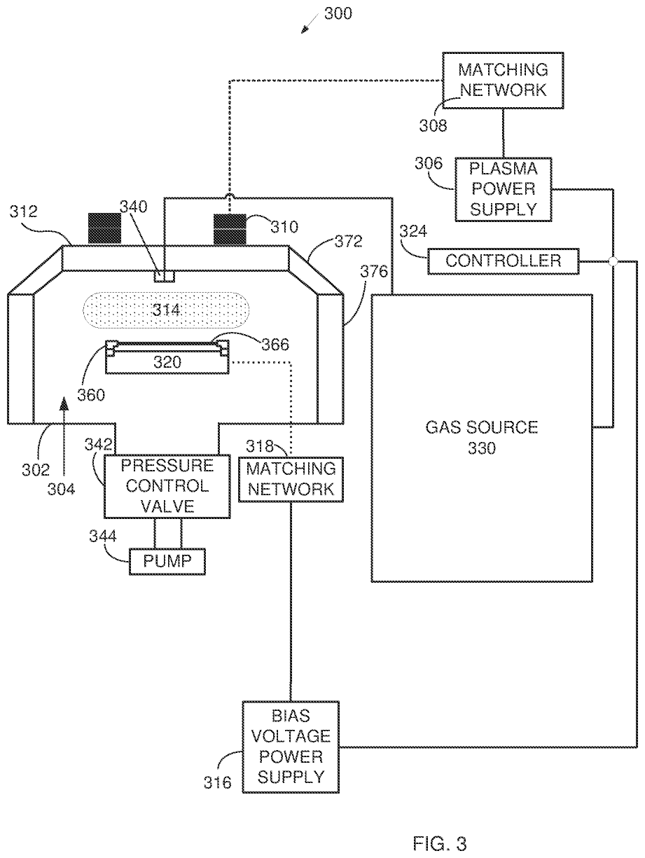

FIG. 3 schematically illustrates an example of a plasma processing chamber system 300 that may be used in an embodiment. The plasma processing chamber system 300 includes a plasma reactor 302 having a plasma processing confinement chamber 304 therein. A plasma power supply 306, tuned by a matching network 308, supplies power to a transformer coupled plasma (TCP) coil 310 located near a dielectric inductive power window 312 to create a plasma 314 in the plasma processing confinement chamber 304 by providing an inductively coupled power. A pinnacle 372 extends from a chamber wall 376 of the plasma processing confinement chamber 304 to the dielectric inductive power window 312 forming a pinnacle ring. The pinnacle 372 is angled with respect to the chamber wall 376 and the dielectric inductive power window 312, such that the interior angle between the pinnacle 372 and the chamber wall 376 and the interior angle between the pinnacle 372 and the dielectric inductive power window 312 are each greater than 90° and less than 180°. The pinnacle 372 provides an angled ring near the top of the plasma processing confinement chamber 304, as shown. The TCP coil (upper power source) 310 may be configured to produce a uniform diffusion profile within the plasma processing confinement chamber 304. For example, the TCP coil 310 may be configured to generate a toroidal power distribution in the plasma 314. The dielectric inductive power window 312 is provided to separate the TCP coil 310 from the plasma processing confinement chamber 304 while allowing energy to pass from the TCP coil 310 to the plasma processing confinement chamber 304. A wafer bias voltage power supply 316 tuned by a matching network 318 provides power to an electrode 320 to set the bias voltage on the substrate 366. The substrate 366 is supported by the electrode 320. A controller 324 controls the plasma power supply 306 and the wafer bias voltage power supply 316.

The plasma power supply 306 and the wafer bias voltage power supply 316 may be configured to operate at specific radio frequencies such as, for example, 13.56 megahertz (MHz), 27 MHz, 2 MHz, 60 MHz, 400 kilohertz (kHz), 2.54 gigahertz (GHz), or combinations thereof. Plasma power supply 306 and wafer bias voltage power supply 316 may be appropriately sized to supply a range of powers in order to achieve desired process performance. For example, in one embodiment, the plasma power supply 306 may supply the power in a range of 50 to 5000 Watts, and the wafer bias voltage power supply 316 may supply a bias voltage of in a range of 20 to 2000 volts (V). In addition, the TCP coil 310 and/or the electrode 320 may be comprised of two or more sub-coils or sub-electrodes. The sub-coils or sub-electrodes may be powered by a single power supply or powered by multiple power supplies.

As shown in FIG. 3, the plasma processing chamber system 300 further includes a gas source/gas supply mechanism 330. The gas source 330 is in fluid connection with plasma processing confinement chamber 304 through a gas inlet, such as a gas injector 340. The gas injector 340 may be located in any advantageous location in the plasma processing confinement chamber 304 and may take any form for injecting gas. Preferably, however, the gas inlet may be configured to produce a “tunable” gas injection profile. The tunable gas injection profile allows independent adjustment of the respective flow of the gases to multiple zones in the plasma process confinement chamber 304. More preferably, the gas injector is mounted to the dielectric inductive power window 312. The gas injector may be mounted on, mounted in, or form part of the power window. The process gases and by-products are removed from the plasma process confinement chamber 304 via a pressure control valve 342 and a pump 344. The pressure control valve 342 and pump 344 also serve to maintain a particular pressure within the plasma processing confinement chamber 304. The pressure control valve 342 can maintain a pressure of less than 1 torr during processing. An edge ring 360 is placed around the substrate 366. The gas source/gas supply mechanism 330 is controlled by the controller 324. A Kiyo by Lam Research Corp. of Fremont, Calif., may be used to practice an embodiment.

In various embodiments, the component may be other parts of a plasma processing chamber, such as confinement rings, edge rings, coronus rings, the electrostatic chucks (ESC), ground rings, chamber liners, door liners, inner electrodes/showerheads, outer electrodes, other components through which radio frequency (RF) energy can pass, crosses, sleeves, pins, nozzles, injectors, forks, arms, etc. Other components of other types of plasma processing chambers may be used. For example, plasma exclusion rings on a bevel etch chamber may be coated in an embodiment. In another example, the plasma processing chamber may be a dielectric processing chamber or conductor processing chamber. In some embodiments, the component body 204 is formed of a ceramic material. In other embodiments, the component body 204 is formed of a silicon (Si) material. In some embodiments, one or more, but not all, surfaces are coated.

According to an embodiment, the powder mixture may be provided by mixing yttria powder with aluminum powder. In one embodiment, the yttria powder is mixed with aluminum powder using a ball mill. The aluminum powder coats the yttria powder. The resulting yttrium aluminum mixture provides a controlled desired yttrium to aluminum ratio of 4:1 to 1:4 by molar number. Other embodiments may provide other methods of coating yttria powder with an aluminum-containing coating at a controlled ratio.

Aerosol deposition provides a high-density coating of solid unmelted material with nanograins. Since the material is not melted, the material is not combined together until the anneal. In addition, unmelted material allows for keeping nanograin size, since melting and solidifying may increase grain size. The embodiments described herein use a powder mixture instead of a YAG powder, a YAM powder, or a YAP powder, as such YAG, YAM and YAP powders are difficult to obtain. In other embodiments, another metal oxide powder instead of yttria powder may be used.

While this disclosure has been described in terms of several preferred embodiments, there are alterations, permutations, modifications, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure.

What is claimed is:

1. A method for coating a component of a plasma processing chamber, wherein the method comprises:
providing a component body; and
aerosol depositing a coating of a powder mixture of an yttrium oxide powder and an aluminum-containing powder onto at least one surface of the component body, wherein the coating has an yttrium to aluminum ratio of 4:1 to 1:4 by molar number.

2. The method, as recited in claim 1, further comprising annealing the coating at a temperature of at least about 900° C. to form the coating into one or more of YAG, YAM or YAP.

3. The method, as recited in claim 2, wherein the component body is made of a ceramic material.

4. The method, as recited in claim 2, wherein the aluminum-containing powder comprises aluminum powder or aluminum oxide powder.

5. The method, as recited in claim 2, wherein the component body forms a dielectric window.

6. A component of a plasma processing chamber, comprising a component body having a coating on a surface of the component body, wherein the coating comprises a porous ternary oxide.

7. The component as recited in claim 6, wherein the porous ternary oxide is formed from a powder mixture of an yttria powder and an aluminum-containing powder.

8. The component as recited in claim 7, wherein the ternary oxide is one or more of YAG, YAM, and YAP.

9. The component as recited in claim 7, wherein the component body is formed of a ceramic material.

10. The component as recited in claim 7, wherein the component body is formed of a silicon material.

11. The component as recited in claim 7, wherein the aluminum-containing powder comprises aluminum powder or aluminum oxide powder.

12. The component as recited in claim 7, wherein the component body forms a dielectric window.

13. The component as recited in claim 6, wherein the coating has a porosity in a range of about 1-20%.

14. The component as recited in claim 6, wherein the coating has a porosity in a range of about 10-20%.

15. The component as recited in claim 6, wherein the coating has a porosity in a range of about 5-20%.

16. The component as recited in claim 6, wherein the coating has a porosity in a range of about 5-10%.

17. The component as recited in claim 6, wherein the coating has an yttrium to aluminum ratio of 4:1 to 1:4 by molar number.

18. A coating on a surface of the component body of a plasma processing chamber, comprising a deposited coating formed from a powder mixture of an yttrium oxide powder and an aluminum-containing powder.

19. The coating as recited in claim 18, wherein the coating is a porous ternary oxide, wherein the porous ternary oxide comprises one of YAG, YAM, and YAP.

20. The coating as recited in claim 18, wherein the aluminum-containing powder comprises aluminum powder or aluminum oxide powder.

21. The coating as recited in claim 18, wherein the coating has a porosity in a range of about 1-20%.

22. The coating as recited in claim 18, wherein the coating has a porosity in a range of about 10-20%.

23. The coating as recited in claim 18, wherein the coating has a porosity in a range of about 5-20%.

24. The coating as recited in claim 18, wherein the coating has a porosity in a range of about 5-10%.

25. The coating as recited in claim 18, wherein the coating has an yttrium to aluminum ratio of 4:1 to 1:4 by molar number.
